(19) United States
(12) Patent Application Publication
(10) Pub. No.: US 2025/0373261 A1
(43) Pub. Date: Dec. 4, 2025

(54) DIGITAL-TO-ANALOG CONVERSION CIRCUIT AND DISPLAY DEVICE

(71) Applicant: WUHAN CHINA STAR OPTOELECTRONICS TECHNOLOGY CO., LTD., Wuhan, Hubei (CN)

(72) Inventor: Zemin HU, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/870,653

(22) PCT Filed: Jun. 29, 2023
(86) PCT No.: PCT/CN2023/103750

§ 371 Date: Nov. 30, 2024

(30) Foreign Application Priority Data
May 12, 2023 (CN) 202310538411.5

(51) Int. Cl. H03M 1/80

(52) U.S. Cl. CPC H03M 1/808

(57) ABSTRACT

The present disclosure discloses a display device and a digital-to-analog conversion circuit, including a first resistance distribution module and a second resistance distribution module, where each first distribution unit included in the first resistance distribution module enables a first resistor therein to be connected between a first voltage terminal and a voltage output node based on a first control signal, and each second distribution unit included in the second resistance distribution module enables a second resistor therein to be connected between the voltage output node and a second voltage terminal according to a second control signal.

### TECHNICAL FIELD

The present disclosure relates to a field of display technology, and in particular to, a digital-to-analog conversion circuit and a display device.

### BACKGROUND

In actual operation and application, it is found that a digital-to-analog conversion circuit in a source driver module occupies a greater space. For example, the four-bits digital-to-analog conversion circuit requires sixteen resistors and a decoder to achieve an output with sixteen grayscale levels. Some functional modules (such as a digital-to-analog conversion circuit) of the driver chip occupy a greater layout space when they are integrated on a glass-based display panel, which is not beneficial to integrating more functions in the display device. Therefore, it is particularly important to improve the structure and the layout space of the digital-to-analog conversion circuit.

### Technical Problems

An embodiment of the present disclosure provides a digital-to-analog conversion circuit and a display device, which are helpful in reducing the layout space occupied by the digital-to-analog conversion circuit.

### Technical Solutions

An embodiment of the present disclosure provides a digital-to-analog conversion circuit, including a first resistance distribution module includes a plurality of first distribution units in series between a first voltage terminal and a voltage output node; each of the first distribution units includes a corresponding one of a plurality of first resistors, and resistance values of the plurality of first resistors are different from each other and the resistance values of the plurality of first resistors are in a geometric sequence; and a second resistance distribution module includes a plurality of second distribution units in series between the voltage output node and a second voltage terminal; each of the second distribution units includes a corresponding one of a plurality of second resistors, and resistance values of the plurality of second resistors are different from each other and the resistance values of the plurality of second resistors are in the geometric sequence. Each of the first distribution units is configured to enable the first resistor included in the first distribution unit to be connected between the first voltage terminal and the voltage output node based on a first control signal, and each of the second distribution units is configured to enable the second resistor included in the second distribution unit to be connected between the voltage output node and the second voltage terminal based on a second control signal.

Alternatively, in some embodiments of the present disclosure, each of the first distribution units includes a first switch device in parallel with the first resistor; and each of the second distribution units includes a second switch device in parallel with the second resistor. The first switch device of each of the first distribution units is configured to enable the first resistor to be connected between the first voltage terminal and the voltage output node based on the first control signal, and the second switch device of each of the second distribution units is configured to enable the second resistor to be connected between the voltage output node and the second voltage terminal based on the second control signal.

Alternatively, in some embodiments of the present disclosure, the first resistance distribution module includes m1 first distribution units, and the resistance value of the first resistor in one of the m1 first distribution units is 2\hat{ }n1; the second resistance distribution module includes m2 second distribution units, and the resistance value of the second resistor in one of the m2 second distribution units is 2\hat{ }n2; and m1>0, m2>0; m1 and m2 are integers, 0≤n1≤(m1−1), 0≤n2≤(m2−1).

Alternatively, in some embodiments of the present disclosure, m1=m2.

Alternatively, in some embodiments of the present disclosure, the second resistance distribution module further includes at least one third distribution unit in series with the plurality of second distribution units; each of the at least one third distribution units includes a third resistor and a third switch device in parallel with the third resistor, and the third switch device of each of the at least one third distribution units is configured to enable the third resistor to be connected between the voltage output node and the second voltage terminal based on a third control signal; and a resistance value of the third resistor included in each of the third distribution units is different from the resistance values of the plurality of second resistors included in the plurality of second distribution units.

Alternatively, in some embodiments of the present disclosure, the resistance value of the third resistor and the resistance values of the plurality of second resistors are not in the geometric sequence.

Alternatively, in some embodiments of the present disclosure, the first resistance distribution module further includes at least one fourth distribution unit in series with the plurality of first distribution units; each of the at least one fourth distribution units includes a fourth resistor and a fourth switch device in parallel with the fourth resistor, and the fourth switch device of each of the at least one fourth distribution units is configured to enable the fourth resistor to be connected between the first voltage terminal and the voltage output node based on a fourth control signal; and a resistance value of the fourth resistor included in each of the fourth distribution units is different from the resistance values of the plurality of first resistors included in the plurality of first distribution units.

Alternatively, in some embodiments of the present disclosure, the resistance value of the fourth resistor and the resistance values of the plurality of first resistors are not in the geometric sequence.

Alternatively, in some embodiments of the present disclosure, each of the first switch device and the second switch device includes a transistor.

Alternatively, in some embodiments of the present disclosure, a control terminal of the first switch device is configured to receive the first control signal, an input terminal of the first switch device is electrically connected to a first terminal of the first resistor corresponding to the first switch device, and an output terminal of the first switch device is electrically connected to a second terminal of the first resistor corresponding to the first switch device.

Alternatively, in some embodiments of the present disclosure, a control terminal of the second switch device is configured to receive the second control signal, an input terminal of the second switch device is electrically connected to a first terminal of the second resistor corresponding to the second switch device, and an output terminal of the second switch device is electrically connected to a second terminal of the second resistor corresponding to the second switch device.

The present disclosure also provides a display device, including any of the above-mentioned digital-to-analog conversion circuits.

### Beneficial Effects

Compared with the related art, the present disclosure discloses a digital-to-analog conversion circuit and a display device. The digital-to-analog conversion circuit includes a first resistance distribution module and a second resistance distribution module, wherein the first resistance distribution module includes a plurality of first distribution units in series between a first voltage terminal and a voltage output node, and the second resistance distribution module includes a plurality of second distribution units in series between the voltage output node and a second voltage terminal, so that each of the first distribution units is configured to enable the first resistor included in the first distribution unit to be connected between the first voltage terminal and the voltage output node based on a first control signal, and each of the second distribution units is configured to enable the second resistor included in the second distribution unit to be connected between the voltage output node and the second voltage terminal based on a second control signal. The first control signals corresponding to the plurality of first distribution units are configured to control the resistance distribution between the first voltage terminal and the voltage output node, and the second control signals corresponding to the plurality of second distribution units are configured to control the resistance distribution between the voltage output node and the second voltage terminal, so that the digital-to-analog conversion circuit may output the expected voltage, which is beneficial to reducing the layout space occupied by the digital-to-analog conversion circuit. The display device includes a digital-to-analog conversion circuit.

### BRIEF DESCRIPTION OF THE DRAWINGS

FIG. 1 is a schematic circuit diagram of a digital-to-analog conversion circuit in the related art.

FIG. 2A to 2D are schematic circuit diagrams of a digital-to-analog conversion circuit according to some embodiments of the present disclosure.

### DETAILED DESCRIPTION

Technical solutions in embodiments of the present disclosure will be clearly and completely described below in conjunction with drawings in the embodiments of the present disclosure. Apparently, the described embodiments are only a part of embodiments of the present disclosure, rather than all the embodiments. Based on the embodiments in the present disclosure, those skilled in the art may make changes in the specific implementations and application scopes according to the concept of the present disclosure and all other embodiments obtained by those skilled in the art without creative work fall within the protection scope of the present disclosure. In addition, it should be understood that the specific implementations described here are only used to illustrate and explain the present disclosure, and are not used to limit the present disclosure. In the present disclosure, unless otherwise stated, directional words used such as “upper” and “lower” generally refer to the upper and lower directions of the device in actual use or working state, and specifically refer to the drawing directions in the drawings; and “inner” and “outer” refer to the outline of the device. The electrical connection can be a direct electrical connection or an indirect electrical connection.

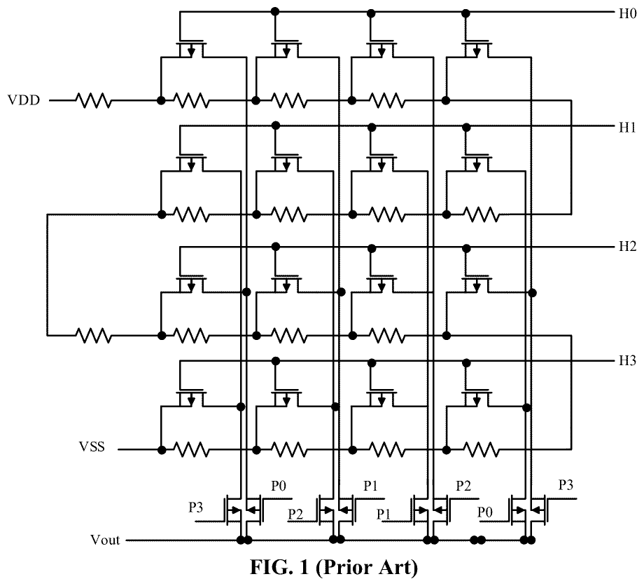

Specifically, FIG. 1 is a schematic circuit diagram of a digital-to-analog conversion circuit in the related art. The existing 4-bit digital-to-analog conversion circuit includes 16 resistors and 16 switch devices to achieve an output with sixteen grayscale levels, and further includes a decoder to obtain a signal required by the digital-to-analog conversion circuit, which causes a greater layout space to be occupied by the digital-to-analog conversion circuit.

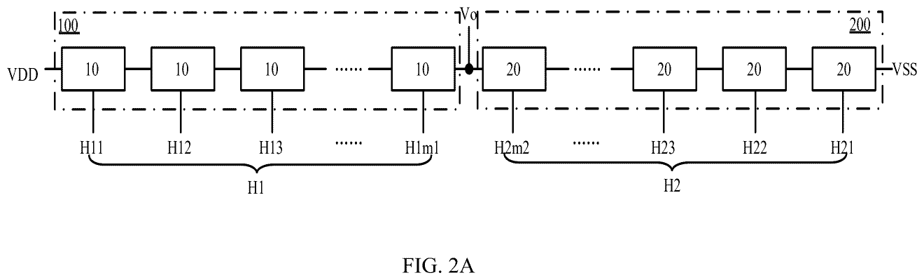

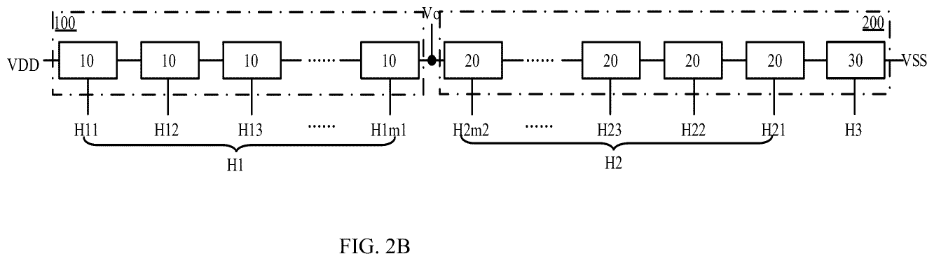

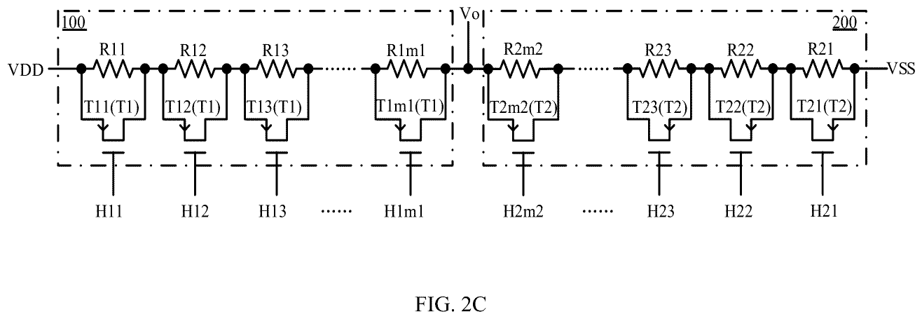

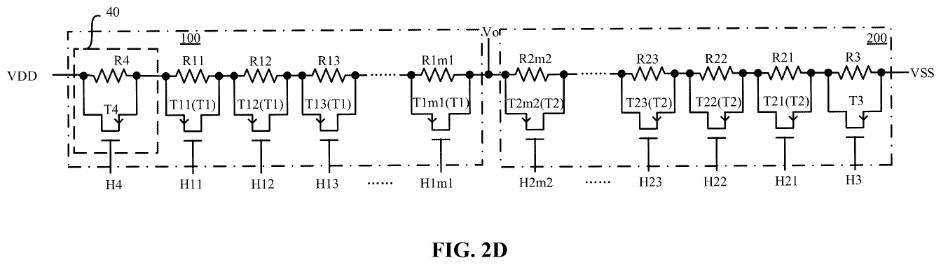

FIGS. 2A to 2D are schematic circuit diagrams of a digital-to-analog conversion circuit according to an embodiment of the present disclosure. An embodiment of the present disclosure provides a digital-to-analog conversion circuit, and the digital-to-analog conversion circuit includes a first resistance distribution module 100 and a second resistance distribution module 200.

The first resistance distribution module 100 includes a plurality of first distribution units 10 in series between a first voltage terminal VDD and a voltage output node Vo. Each of the first distribution units 10 receives a first control signal H1, and the plurality of first distribution units 10 are configured to control resistance distribution between the first voltage terminal VDD and the voltage output node Vo according to the corresponding first control signal H1.

The second resistance distribution module 200 includes a plurality of second distribution units 20 in series between the voltage output node Vo and a second voltage terminal VSS. Each of the second distribution units 20 receives a second control signal H2, and the plurality of second distribution units 20 are configured to control the resistance distribution between the voltage output node Vo and the second voltage terminal VSS according to the corresponding second control signal H2.

The digital-to-analog conversion circuit includes the plurality of first distribution units 10 and the plurality of second distribution units 20. Thus, the digital-to-analog conversion circuit controls the resistance distribution between the first voltage terminal VDD and the voltage output node Vo, the resistance distribution between the voltage output node Vo and the second voltage terminal VSS, and the resistance distribution between the first voltage terminal VDD and the second voltage terminal VSS according to the plurality of first control signals H1 and the plurality of second control signals H2, so that the digital-to-analog conversion circuit outputs a plurality of expected voltage signals in a relatively simple circuit configure, which is beneficial to reducing the layout space occupied by the digital-to-analog conversion circuit.

For example, the first resistance distribution module 100 includes m1 first distribution units 10, and the first control signals H1 received by the m1 first distribution units 10 include control signals H11, H12, H13, . . . , H1m1. The second resistance distribution module 200 includes m2 second distribution units 20, and the second control signals H2 received by the m2 second distribution units 20 include control signals H21, H22, H23, . . . , H2m2. Where m1>0, m2>0, and m1 and m2 are integers.

Alternatively, continue to refer to FIG. 2B and FIG. 2D, each of the first distribution units 10 includes a first resistor, and each of the second distribution units 20 includes a second resistor. The resistance values of the first resistors are different from each other and the resistance values of the first resistors are in a geometric sequence. The resistance values of the second resistors are different from each other and the resistance values of the second resistors are in the geometric sequence. Therefore, the digital-to-analog conversion circuit may output a plurality of expected voltage signals, so that the display device including the digital-to-analog conversion circuit may achieve an requirement of an exponentially increasing grayscale only by using a linearly increasing number of devices, so that the layout space occupied by the digital-to-analog conversion circuit in the display device including the digital-to-analog conversion circuit may be significantly reduced, which is beneficial for the display device to having more functions.

Correspondingly, when each of the first distribution units 10 includes the first resistor and each of the second distribution units 20 includes the second resistor. Each of the first distribution units 10 is configured to enable the first resistor included therein to be connected between the first voltage terminal VDD and the voltage output node Vo according to the first control signal H1. Each of the second distribution units 20 is configured to enable the second resistor included therein to be connected between the voltage output node Vo and the second voltage terminal VSS according to the second control signal H2. Thus, the number of the first resistors being connected between the first voltage terminal VDD and the voltage output node Vo by the plurality of first control signals H1 may be controlled, thereby controlling the resistance distribution between the first voltage terminal VDD and the voltage output node Vo. The number of the second resistors being connected between the voltage output node Vo and the second voltage terminal VSS by the plurality of second control signals H2 may be controlled, thereby controlling the resistance distribution between the voltage output node Vo and the second voltage terminal VSS. By controlling the resistance distribution between the first voltage terminal VDD and the voltage output node Vo and the resistance distribution between the voltage output node Vo and the second voltage terminal VSS, the resistance distribution between the first voltage terminal VDD and the second voltage terminal VSS may be controlled, so that the digital-to-analog conversion circuit outputs the expected voltage signal through the voltage output node Vo according to the resistance distribution between the first voltage terminal VDD and the second voltage terminal VSS, the resistance distribution between the first voltage terminal VDD and the voltage output node Vo, the resistance distribution between the voltage output node Vo and the second voltage terminal VSS, the first voltage terminal VDD and the second voltage terminal VSS.

Alternatively, continue to refer to FIG. 2B and FIG. 2D, each of the first distribution units 10 includes a first switch device T1 in parallel with the first resistor and each of the second distribution units 20 includes a second switch device T2 in parallel with the second resistor. The first switch device T1 of each of the first distribution units 10 is configured to enable the first resistor to be connected between the first voltage terminal VDD and the voltage output node Vo according to the corresponding first control signal H1, to control the resistance distribution between the first voltage terminal VDD and the voltage output node Vo. The second switch device T2 of each of the second distribution units 20 is configured to enable the second resistor to be connected between the voltage output node Vo and the second voltage terminal VSS according to the corresponding second control signal H2, to control the resistance distribution between the voltage output node Vo and the second voltage terminal VSS.

For example, the first resistance distribution module 100 includes m1 first distribution units 10, and the first switch devices respectively corresponding to the m1 first distribution units 10 may include switch devices T11, T12, T13, . . . , T1m1. The second resistance distribution module 200 includes m2 second distribution units 20, and the second switch devices respectively corresponding to the m2 second distribution units 20 may include switch devices T21, T22, T23, . . . , T2m2.

Alternatively, a control terminal of the first switch device T1 included in each first distribution unit 10 is configured to receive the first control signal H1, an input terminal of the first switch device T1 is electrically connected to a first terminal of the first resistor corresponding to the first switch device T1, and an output terminal of the first switch device T1 is electrically connected to a second terminal of the first resistor corresponding to the first switch device T1.

Alternatively, a control terminal of the second switch device T2 included in each second distribution unit 20 is configured to receive the second control signal H2, an input terminal of the second switch device T2 is electrically connected to a first terminal of the second resistor corresponding to the second switch device T2, and an output terminal of the second switch device T2 is electrically connected to a second terminal of the second resistor corresponding to the second switch device T2.

Alternatively, at least one of the first switch device T1 and the second switch device T2 includes a transistor (such as field effect transistors, thin film transistors), etc. A control terminal of the transistor is configured to control turn-on and turn-off of the switch device according to a control signal. Alternatively, the control terminal of the transistor may be a gate. An input terminal of the transistor may be one of a source and a drain, and an output terminal of the transistor may be the other of the source and the drain.

Alternatively, the first resistance distribution module 100 includes m1 first distribution units 10, and the resistance value of the first resistor corresponding to one of the m1 first distribution units 10 is p1\hat{ }n1 (that is, the resistance values of the first resistors respectively corresponding to the m1 first distribution units 10 are R11=(p1\hat{ }0)R=1R, R12=(p1\hat{ }1)R, R13=(p1\hat{ }2)R, . . . , R1m1=(p1\hat{ }(m1−1))R. The second resistance distribution module 200 includes m2 second distribution units 20, and the resistance value of the second resistor corresponding to one of the m2 second distribution units 20 is p2\hat{ }n2 (that is, the resistance values of the second resistors respectively corresponding to the m2 second distribution units 20 are R21=(p2\hat{ }0)R=1R, R22=(p1\hat{ }1)R, R23=(p1\hat{ }2)R, . . . , Rm2=(p1\hat{ }(m2−1))R). Where p1>1, p2>1, 0≤n1≤(m1−1), and 0≤n2≤(m2−1). By establishing a relationship between the number of the first distribution units 10 included in the first resistance distribution module 100 and the resistance values of the first resistors correspondingly included in the plurality of first distribution units 10, and establishing a relationship between the number of the second distribution units 20 included in the second resistance distribution module 200 and the resistance values of the second resistors correspondingly included in the plurality of second distribution units 20, the voltage signal output by the digital-to-analog conversion circuit may meet the voltage requirement corresponding to the grayscale level that may be achieved by the display device including the digital-to-analog conversion circuit.

It is understandable that R may be set to have different values according to requirements. Alternatively, R may be set to have different values for the second resistance distribution module 200 and the first resistance distribution module 100.

Alternatively, p1 may be 2, 3, 4, 5, 6, 7, 8, 9, 10, etc.; Alternatively, p2 may be 2, 3, 4, 5, 6, 7, 8, 9, 10, etc., so that the voltage signal output by the digital-to-analog conversion circuit may meet the display requirements of the display device including the digital-to-analog conversion circuit for realizing different grayscale levels.

Alternatively, the resistance values of the plurality of first resistors and the resistance values of the plurality of second resistors may be determined according to grayscale levels that can be achieved by the display device to which the digital-to-analog conversion circuit is applied.

Alternatively, the first resistance distribution module 100 includes m1 first distribution units 10, and the resistance value of the first resistor corresponding to one of the m1 first distribution units 10 is 2\hat{ }n1. The second resistance distribution module 200 includes m2 second distribution units 20, and the resistance value of the second resistor corresponding to one of the m2 second distribution units 20 is 2\hat{ }n2. Therefore, when the grayscale levels that the display device may achieve are 2\hat{ }n, the voltage signal output by the digital-to-analog conversion circuit can meet the voltage requirement of the display device; where, m1>0, m2>0; m1 and m2 are integers, 0≤n1≤(m1−1), and 0≤n2≤(m2−1).

Alternatively, n>0. Alternatively, n is 2, 3, 4, 5, 6, 7, 8, 9, 10, etc. Correspondingly, 2\hat{ }n is 4, 8, 16, 32, 64, 128, 256, 512, 1024, etc.

Taking the first resistance distribution module 100 including four (i.e., m1=4) first distribution units 10, the second resistance distribution module 200 including four (i.e., m2=4) second distribution units 20, and the grayscale levels that the display device may achieve are 2\hat{ }n as an example, the resistance values of the plurality of first resistors are in a geometric sequence and the resistance values of the plurality of second resistors are in the geometric sequence are described.

The first resistance distribution module 100 includes four (i.e., m1=4) first distribution units 10, and the resistance values of the first resistors corresponding to the four first distribution units 10 are 1R, 2R, 4R, and 8R, respectively. The second resistance distribution module 200 includes four (i.e., m2=4) second distribution units 20, and the resistance values of the second resistors corresponding to the four second distribution units 20 are 1R, 2R, 4R, and 8R, respectively.

Similarly, the grayscale levels that the display device may realize including the digital-to-analog conversion circuit are 2\hat{ }n. When m1=5, the resistance values of the first resistors corresponding to the five first distribution units 10 are 1R, 2R, 4R, 8R, and 16R, respectively; when m1=6, the resistance values of the first resistors corresponding to the six first distribution units 10 are 1R, 2R, 4R, 8R, 16R, and 32R, respectively. Similarly, when m1 is 1, 2, 3, 7, 8, 9, 10, 11, etc., the geometric sequence formed by the resistance values of the plurality of first resistors may be obtained. Similarly, it can be obtained that the grayscale levels that may be achieved by the display device including the digital-to-analog conversion circuit are 2\hat{ }n, and when m2 is 1, 2, 3, 5, 6, 7, 8, 9, 10, 11, etc., the geometric sequence formed by the resistance values of the plurality of second resistors may be obtained.

Similar to the grayscale levels of 2\hat{ }n that may be achieved by the display device using the digital-to-analog conversion circuit, it can also be obtained that when the grayscale levels that may be achieved by the display device including the digital-to-analog conversion circuit are 3\hat{ }n, 5\hat{ }n, 7\hat{ }n, 10\hat{ }n, 11\hat{ }n, etc, the geometric sequence formed by the resistance values of the plurality of first resistors and the geometric sequence formed by the resistance values of the plurality of second resistors.

Continue to refer to FIG. 2B, taking the first resistance distribution module 100 including four (i.e., m1=4) first distribution units 10, the second resistance distribution module 200 including four (i.e., m2=4) second distribution units 20, and the grayscale levels that may be achieved by the display device are 2\hat{ }n as an example, the voltage signal that may be output by the digital-to-analog conversion circuit may be illustrated.

Four first distribution units 10 include a first sub-distribution unit, a second sub-distribution unit, a third sub-distribution unit, and a fourth sub-distribution unit. The resistance value R11 of the first resistor included in the first sub-distribution unit is 1R, the resistance value R12 of the first resistor included in the second sub-distribution unit is 2R, the resistance value R13 of the first resistor included in the third sub-distribution unit is 4R, and the resistance value R14 of the first resistor included in the fourth sub-distribution unit is 8R.

Then, the four first distribution units 10 may control the resistance between the first voltage terminal VDD and the voltage output node Vo to be 0R, 1R, 2R, 3R, 4R, 5R, 6R, 7R, 8R, 9R, 10R, 11R, 12R, 13R, 14R, 15R under the control of the first control signal H1.

Specifically, when the four first distribution units 10 enable the four first resistors not to be connected between the first voltage terminal VDD and the voltage output node Vo under the control of the first control signal H1 (i.e., the first control signal H1 includes the first sub-control signal H11, the second sub-control signal H12, the third sub-control signal H13 and the fourth sub-control signal H14=H1m1), the resistance between the first voltage terminal VDD and the voltage output node Vo is 0R.

Under the condition that only the first sub-distribution unit of the four first distribution units 10 controls the first resistor with the resistance value of R11 to be connected between the first voltage terminal VDD and the voltage output node Vo according to the first sub-control signal H11, the resistance between the first voltage terminal VDD and the voltage output node Vo is 1R.

Under the condition that the second sub-distribution unit of the four first distribution units 10 controls the first resistor with the resistance value of R12 to be connected between the first voltage terminal VDD and the voltage output node Vo according to the second sub-control signal H12, the resistance between the first voltage terminal VDD and the voltage output node Vo is 2R.

Under the condition that only the first sub-distribution unit and the second sub-distribution unit in the four first distribution units 10 control the first resistors with the resistance values of R11 and R12 to be connected between the first voltage terminal VDD and the voltage output node Vo according to the first sub-control signal H11 and the second sub-control signal H12, the resistance between the first voltage terminal VDD and the voltage output node Vo is 3R.

Under the condition that only the third sub-distribution unit of the four first distribution units 10 controls the first resistor with the resistance value of R13 to be connected between the first voltage terminal VDD and the voltage output node Vo according to the third sub-control signal H13, the resistance between the first voltage terminal VDD and the voltage output node Vo is 4R.

Under the condition that only the first sub-distribution unit and the third sub-distribution unit in the four first distribution units 10 control the first resistors with the resistance values of R11 and R13 to be connected between the first voltage terminal VDD and the voltage output node Vo according to the first sub-control signal H11 and the third sub-control signal H13, the resistance between the first voltage terminal VDD and the voltage output node Vo is 5R.

Under the condition that only the second sub-distribution unit and the third sub-distribution unit in the four first distribution units 10 control the first resistors with the resistance values of R12 and R13 to be connected between the first voltage terminal VDD and the voltage output node Vo according to the second sub-control signal H12 and the third sub-control signal H13, the resistance between the first voltage terminal VDD and the voltage output node Vo is 6R.

Under the condition that only the first sub-distribution unit, the second sub-distribution unit and the third sub-distribution unit in the four first distribution units 10 control the first resistors with the resistance values of R11, R12, and R13 to be connected between the first voltage terminal VDD and the voltage output node Vo according to the first sub-control signal H11, the second sub-control signal H12 and the third sub-control signal H13, the resistance between the first voltage terminal VDD and the voltage output node Vo is 7R.

Under the condition that only the fourth sub-distribution unit of the four first distribution units 10 controls the first resistor with the resistance value of R14 to be connected between the first voltage terminal VDD and the voltage output node Vo according to the first sub-control signal H14, the resistance between the first voltage terminal VDD and the voltage output node Vo is 8R.

Under the condition that the first sub-distribution unit and the fourth sub-distribution unit of the four first distribution units 10 control the first resistors with the resistance values of R11 and R14 to be connected between the first voltage terminal VDD and the voltage output node Vo according to the first sub-control signal H11 and the fourth sub-control signal H14, the resistance between the first voltage terminal VDD and the voltage output node Vo is 9R.

Under the condition that the second sub-distribution unit and the fourth sub-distribution unit of the four first distribution units 10 control the first resistors with the resistance values of R12 and R14 to be connected between the first voltage terminal VDD and the voltage output node Vo according to the second sub-control signal H12 and the fourth sub-control signal H14, the resistance between the first voltage terminal VDD and the voltage output node Vo is 10R.

Under the condition that the first sub-distribution unit, the second sub-distribution unit and the fourth sub-distribution unit of the four first distribution units 10 control the first resistors with the resistance values of R11, R12, and R14 to be connected between the first voltage terminal VDD and the voltage output node Vo according to the first sub-control signal H11, the second sub-control signal H12, and the fourth sub-control signal H14, the resistance between the first voltage terminal VDD and the voltage output node Vo is 11R.

Under the condition that only the third sub-distribution unit and the fourth sub-distribution unit of the four first distribution units 10 control the first resistors with the resistance values of R13 and R14 to be connected between the first voltage terminal VDD and the voltage output node Vo according to the third sub-control signal H13 and the fourth sub-control signal H14, the resistance between the first voltage terminal VDD and the voltage output node Vo is 12R.

Under the condition that only the first sub-distribution unit, the third sub-distribution unit, and the fourth sub-distribution unit of the four first distribution units 10 control the first resistors with the resistance values of R11, R13, and R14 to be connected between the first voltage terminal VDD and the voltage output node Vo according to the first sub-control signal H11, the third sub-control signal H13, and the fourth sub-control signal H14, the resistance between the first voltage terminal VDD and the voltage output node Vo is 13R.

Under the condition that only the second sub-distribution unit, the third sub-distribution unit, and the fourth sub-distribution unit of the four first distribution units 10 control the first resistors with the resistance values of R12, R13, and R14 to be connected between the first voltage terminal VDD and the voltage output node Vo according to the second sub-control signal H12, the third sub-control signal H13, and the fourth sub-control signal H14, the resistance between the first voltage terminal VDD and the voltage output node Vo is 14R.

Under the condition that the first sub-distribution unit, the second sub-distribution unit, the third sub-distribution unit, and the fourth sub-distribution unit of the four first distribution units 10 control the first resistors with the resistance values of R11, R12, R13, and R14 to be connected between the first voltage terminal VDD and the voltage output node Vo according to the first sub-control signal H11, the second sub-control signal H12, the third sub-control signal H13, and the fourth sub-control signal H14, the resistance between the first voltage terminal VDD and the voltage output node Vo is 15R.

Similarly, the resistance values of the four second distribution units 20 are that: R21=1R, R22=2R, R23=4R, and R24=8R. Then, the four second distribution units 20 may control the resistance between the voltage output node Vo and the second voltage terminal VSS to be 0R, 1R, 2R, 3R, 4R, 5R, 6R, 7R, 8R, 9R, 10R, 11R, 12R, 13R, 14R, and 15R under the control of the second control signal H2.

Accordingly, Rb/(Ra+Rb) may be obtained as shown in Table 1, and then the voltage signal Vout output by the digital-to-analog conversion circuit is obtained based on the data in Table 1. The portion of the data in Table 1 except for repeated data may enable the digital-to-analog conversion circuit to output 146 voltage signals in total. Therefore, the digital-to-analog conversion circuit of an embodiment of the present disclosure may realize the output of the plurality of voltage signals by using a relatively simple circuit configuration thereof, which is beneficial to reducing the layout space occupied by the digital-to-analog conversion circuit.

Where Vout=Rb(VDD−VSS)/(Ra+Rb). Ra is the resistance between the first voltage terminal VDD and the voltage output node Vo by the plurality of first distribution units 10 under the control of the first control signal H1. Rb is the resistance between the voltage output node Vo and the second voltage terminal VSS by the plurality of second distribution units 20 under the control of the second control signal H2. At least one first resistor or at least one second resistor of the plurality of first distribution units 10 and the plurality of second distribution units 20 is controlled by the plurality of first control signals H1 and the plurality of second control signals H2 to be connected between the first voltage terminal VDD and the second voltage terminal VSS, thereby avoiding the situation that there is no resistor connected between the first voltage terminal VDD and the second voltage terminal VSS, and the digital-to-analog conversion circuit has no output.

TABLE 1

| | Rb | | | | | | | |
|---|---|---|---|---|---|---|---|---|
| Ra | 0 | 1 | 2 | 3 | 4 | 5 | 6 | 7 |
| 0 | / | 0 | 0 | 0 | 0 | 0 | 0 | 0 |
| 1 | 1 | 1/2 | 1/3 | 1/4 | 1/5 | 1/6 | 1/7 | 1/8 |
| 2 | 1 | 2/3 | 1/2 | 2/5 | 1/3 | 2/7 | 1/4 | 2/9 |
| 3 | 1 | 3/4 | 3/5 | 1/2 | 3/7 | 3/8 | 1/3 | 3/10 |
| 4 | 1 | 4/5 | 2/3 | 4/7 | 1/2 | 4/9 | 2/5 | 4/11 |
| 5 | 1 | 5/6 | 5/7 | 5/8 | 5/9 | 1/2 | 5/11 | 5/12 |
| 6 | 1 | 6/7 | 3/4 | 2/3 | 3/5 | 6/11 | 1/2 | 6/13 |
| 7 | 1 | 7/8 | 7/9 | 7/10 | 7/11 | 7/12 | 7/13 | 1/2 |
| 8 | 1 | 8/9 | 4/5 | 8/11 | 2/3 | 8/13 | 4/7 | 8/15 |
| 9 | 1 | 8/9 | 9/11 | 3/4 | 9/13 | 9/14 | 3/5 | 9/16 |
| 10 | 1 | 10/11 | 5/6 | 10/13 | 5/7 | 2/3 | 5/8 | 10/17 |
| 11 | 1 | 11/12 | 11/13 | 11/14 | 11/15 | 11/16 | 11/17 | 11/18 |
| 12 | 1 | 12/13 | 6/7 | 4/5 | 3/4 | 12/17 | 2/3 | 12/19 |
| 13 | 1 | 13/14 | 13/15 | 13/16 | 13/17 | 13/18 | 13/19 | 13/20 |
| 14 | 1 | 14/15 | 7/8 | 14/17 | 7/9 | 14/19 | 7/10 | 2/3 |
| 15 | 1 | 15/16 | 15/17 | 5/6 | 15/19 | 3/4 | 5/7 | 15/22 |
| | Rb | | | | | | | |
| Ra | 8 | 9 | 10 | 11 | 12 | 13 | 14 | 15 |
| 0 | 0 | 0 | 0 | 0 | 0 | 0 | 0 | 0 |
| 1 | 1/9 | 1/10 | 1/11 | 1/12 | 1/13 | 1/14 | 1/15 | 1/16 |
| 2 | 1/5 | 2/11 | 1/6 | 2/13 | 1/7 | 2/15 | 1/8 | 2/17 |
| 3 | 3/11 | 1/4 | 3/13 | 3/14 | 1/5 | 3/16 | 3/17 | 1/6 |
| 4 | 1/3 | 4/13 | 2/7 | 4/15 | 1/4 | 4/17 | 2/9 | 4/19 |
| 5 | 5/13 | 5/14 | 1/3 | 5/16 | 5/17 | 5/18 | 5/19 | 1/4 |
| 6 | 3/7 | 2/5 | 3/8 | 6/17 | 1/3 | 6/19 | 3/10 | 2/7 |
| 7 | 7/15 | 7/16 | 7/17 | 7/18 | 7/19 | 7/20 | 1/3 | 7/22 |
| 8 | 1/2 | 8/17 | 4/9 | 8/19 | 2/5 | 8/21 | 4/11 | 8/23 |
| 9 | 9/17 | 1/2 | 9/19 | 9/20 | 3/7 | 9/22 | 9/23 | 3/8 |
| 10 | 5/9 | 10/19 | 1/2 | 10/21 | 5/11 | 10/23 | 5/12 | 2/5 |
| 11 | 11/19 | 11/20 | 11/21 | 1/2 | 11/23 | 11/24 | 11/25 | 11/26 |
| 12 | 3/5 | 4/7 | 6/11 | 12/23 | 1/2 | 12/25 | 6/13 | 4/9 |
| 13 | 13/21 | 13/22 | 13/23 | 13/24 | 13/25 | 1/2 | 13/27 | 13/28 |
| 14 | 7/1 | 14/23 | 7/12 | 14/25 | 7/13 | 14/27 | 1/2 | 14/29 |
| 15 | 15/23 | 5/8 | 3/5 | 15/26 | 5/9 | 15/28 | 15/29 | 1/2 |

Alternatively, by adjusting the resistance values of the first resistor and the second resistor, the plurality of voltage signals output by the digital-to-analog conversion circuit include the gamma voltage corresponding to the grayscale level that may be achieved by the display device including the digital-to-analog conversion circuit. Therefore, the digital-to-analog conversion circuit may also realize the adjustment of the gamma voltage. For example, the data in Table 1 is taken as an example, and if the display panel needs to achieve 16 grayscale levels, the 146 kinds of voltage signals output by the digital-to-analog conversion circuit may include the voltage corresponding to the 16 grayscale levels, so that the digital-to-analog conversion circuit may also realize the adjustment of the gamma voltage.

Alternatively, when the plurality of voltage signals output by the digital-to-analog conversion circuit do not include the gamma voltage corresponding to the grayscale level that may be achieved by the display device including the digital-to-analog conversion circuit, the adjustment of the gamma voltage may be achieved by providing the digital-to-analog conversion circuit with different voltages from an external binding point. At this time, since the adjustment of the gamma voltage is based on a gamma voltage obtained by fine-tuning the plurality of voltage signals output by the relatively simple digital-to-analog conversion circuit, even if the present disclosure and the prior art both need to provide the digital-to-analog conversion circuit with different voltages from an external binding point to achieve the adjustment of the gamma voltage, an embodiment of the present disclosure still has the advantage of reducing the layout space occupied by the digital-to-analog conversion circuit, and the number of voltage signals output by the digital-to-analog conversion circuit of an embodiment of the present disclosure is increased, which is more beneficial to achieving fine adjustment of the gamma voltage.

Alternatively, the number of the first distribution units 10 included in the first resistance distribution module 100 may be same as the number of the second distribution units 20 included in the second resistance distribution module 200 (i.e., m1=m2), so that the resistance values of the plurality of first resistors included in the first resistance distribution module 100 and the resistance values of the plurality of second resistors included in the second resistance distribution module 200 may be equal in a one-to-one correspondence, thereby reducing the difficulty of device selection and reducing the manufacture cost.

Alternatively, the number of the first distribution units 10 included in the first resistance distribution module 100 may be not equal to the number of the second distribution units 20 included in the second resistance distribution module 200 (i.e., m1 m2), and thus the sum of the resistance values of the plurality of first resistors included in the first resistance distribution module 100 is different from the sum of the resistance values of the plurality of second resistors included in the second resistance distribution module 200, so that the voltage signal output by the digital-to-analog conversion circuit may meet different design requirements.

Alternatively, continue to refer to FIG. 2C to FIG. 2D, the second resistance distribution module 200 further includes at least one third distribution unit 30 in series with a plurality of second distribution units 20. Each of the third distribution units 30 is configured to adjust the resistance distribution between the voltage output node Vo and the second voltage terminal VSS according to a third control signal H3.

Alternatively, each of the third distribution units 30 includes a third resistor and a third switch device T3 in parallel with the third resistor, and the third switch device T3 of each of the third distribution units 30 is configured to enable the corresponding third resistor to be connected between the voltage output node Vo and the second voltage terminal VSS according to the third control signal H3.

Alternatively, the resistance value of the third resistor included in each of the third distribution units 30 may be set according to the requirements for an expected gamma voltage (that is, the resistance value of the third resistor included in each of the third distribution units 30 may be the same as or different from the resistance value of the second resistor included in the plurality of second distribution units 20). If there is a special setting requirement for the gamma voltage, the voltage signal output by the digital-to-analog conversion circuit may be controlled by setting the third resistor and controlling whether the third resistor is connected between the voltage output node Vo and the second voltage terminal VSS. Therefore, the number of voltage signals output by the digital-to-analog conversion circuit may be increased, so that the digital-to-analog conversion circuit may also realize the adjustment of the gamma voltage.

Alternatively, the resistance value of the third resistor and the resistance values of the plurality of second resistors are not in a geometric sequence, so that the digital-to-analog conversion circuit may output the expected gamma voltage.

Taking the first resistance distribution module 100 includes four (i.e., m1=4) first distribution units 10, the second resistance distribution module 200 includes four (i.e., m2=4) second distribution units 20, R11=R21=1R, R12=R22=2R, R13=R23=4R, R14=R24=8, and the grayscale levels that may be achieved by the display device are 2\hat{ }n as an example, the working principle of the digital-to-analog conversion circuit is illustrated.

Under the condition that the plurality of first distribution units 10 and the plurality of second distribution units 20 are in operation, and the third distribution unit 30 is not in operation (i.e., the third resistor with a resistance value of R3 is not enabled to be connected between the voltage output node Vo and the second voltage terminal VSS under the control of the third control signal 113), the digital-to-analog conversion circuit may output 146 kinds of normal linear voltages. If a certain gamma voltage division cannot be achieved by the plurality of first distribution units 10 and the plurality of second distribution units 20, it may be achieved by the plurality of first distribution units 10 and the plurality of second distribution units 20 in cooperation with the third distribution unit 30. If a 29/32 voltage division is expected, a resistance value of 3R may be selected from the plurality of first distribution units 10 (i.e., the first resistances R11 and R12 are controlled by the control signals H11 and H12 to be between the first voltage terminal VDD and the voltage output node Vo, and the resistance R13, R14, R21, R22, R23, and R24 are controlled by the control signals H13, H14, H21, H22, H23, and H24 not to be between the first voltage terminal VDD and the voltage output node Vo), so that the third resistor controlled by the third control signal H3 is set to have a resistance of 29R and is connected between the voltage output node Vo and the first voltage terminal VDD. Usually, the expected gamma voltage may be obtained only by setting the third distribution unit 30, without providing the digital-to-analog conversion circuit with different voltages from an external binding point to achieve the adjustment of the gamma voltage. R3 may be the resistance value of a single third resistor, or the sum of the resistance values of the plurality of third resistors.

Similarly, the first resistance distribution module 100 further includes at least one fourth distribution unit in series with the plurality of first distribution units 10; each of the fourth distribution units is configured to adjust the resistance distribution between the first voltage terminal VDD and the voltage output node Vo according to a fourth control signal.

Alternatively, each of the fourth distribution units includes a fourth resistor and a fourth switch device in parallel with the fourth resistor, and the fourth switch device of each of the fourth distribution units is configured to enable the fourth resistor corresponding to the fourth distribution unit to be connected between the first voltage terminal VDD and the voltage output node Vo according to the fourth control signal.

Alternatively, the resistance value of the fourth resistor included in each of the fourth distribution units is different from or the same as the resistance value of the first resistor included in the plurality of first distribution units 10.

Alternatively, the resistance value of the fourth resistor and the resistance values of the first resistors are not in a geometric sequence, so that the expected gamma voltage may be obtained only by setting the fourth distribution unit, without providing the digital-to-analog conversion circuit with different voltages from an external binding point to achieve the adjustment of the gamma voltage.

Alternatively, at least one of the third switch devices and the fourth switch device includes a transistor (such as field effect transistors, thin film transistors) or the like.

The present disclosure also provides a display device, including any of the above-mentioned digital-to-analog conversion circuits and a display panel. Alternatively, the display panel includes a passive light-emitting display panel (such as a liquid crystal display panel) and a self-luminous display panel (such as a display panel including devices such as organic light-emitting diodes, sub-millimeter light-emitting diodes, and/or micro light-emitting diodes).

Specific examples are used herein to illustrate the principles and implementations of the present disclosure. The description of the above embodiments is only used to help understand the method and core idea of the present disclosure. Meanwhile, for a person skilled in the art, according to the idea of the present disclosure, there will be changes in the specific implementation methods and application scope. In summary, the content of this description should not be understood as a limitation on the present disclosure.

1. A digital-to-analog conversion circuit, comprising:
a first resistance distribution module comprises a plurality of first distribution units in series between a first voltage terminal and a voltage output node; each of the first distribution units comprises a corresponding one of a plurality of first resistors, and resistance values of the plurality of first resistors are different from each other and the resistance values of the plurality of first resistors are in a geometric sequence; and
a second resistance distribution module comprises a plurality of second distribution units in series between the voltage output node and a second voltage terminal; each of the second distribution units comprises a corresponding one of a plurality of second resistors, and resistance values of the plurality of second resistors are different from each other and the resistance values of the plurality of second resistors are in the geometric sequence,
wherein each of the first distribution units is configured to enable the first resistor comprised in the first distribution unit to be connected between the first voltage terminal and the voltage output node based on a first control signal, and each of the second distribution units is configured to enable the second resistor comprised in the second distribution unit to be connected between the voltage output node and the second voltage terminal based on a second control signal.

2. The digital-to-analog conversion circuit according to claim 1, wherein,
each of the first distribution units comprises a first switch device in parallel with the first resistor; and
each of the second distribution units comprises a second switch device in parallel with the second resistor; and
wherein the first switch device of each of the first distribution units is configured to enable the first resistor to be connected between the first voltage terminal and the voltage output node based on the first control signal, and the second switch device of each of the second distribution units is configured to enable the second resistor to be connected between the voltage output node and the second voltage terminal based on the second control signal.

3. The digital-to-analog conversion circuit according to claim 1, wherein,
a number of the plurality of first distribution units is m1, and the resistance value of the first resistor in an (n1+1)-th one of the plurality of first distribution units is (2\hat{ }n1)R; and
a number of the plurality of second distribution units is m2, and the resistance value of the second resistor in an (n2+1)-th one of the plurality of second distribution units is (2\hat{ }n2)R; and
wherein m1>0, m2>0; m1 and m2 are integers, 0≤n1≤(m1−1), 0≤n2≤(m2−1), and R is an unit cell of the resistance value and is set to have different values according to requirements.

4. The digital-to-analog conversion circuit according to claim 3, wherein m1 is equal to m2.

5. The digital-to-analog conversion circuit according to claim 1, wherein the second resistance distribution module further comprises at least one third distribution unit in series with the plurality of second distribution units; each of the at least one third distribution units comprises a third resistor and a third switch device in parallel with the third resistor, and the third switch device of each of the at least one third distribution units is configured to enable the third resistor to be connected between the voltage output node and the second voltage terminal based on a third control signal; and
wherein a resistance value of the third resistor comprised in each of the third distribution units is different from the resistance values of the plurality of second resistors comprised in the plurality of second distribution units.

6. The digital-to-analog conversion circuit according to claim 5, wherein the resistance value of the third resistor and the resistance values of the plurality of second resistors are not in the geometric sequence.

7. The digital-to-analog conversion circuit according to claim 1, wherein the first resistance distribution module further comprises at least one fourth distribution unit in series with the plurality of first distribution units; each of the at least one fourth distribution units comprises a fourth resistor and a fourth switch device in parallel with the fourth resistor, and the fourth switch device of each of the at least one fourth distribution units is configured to enable the fourth resistor to be connected between the first voltage terminal and the voltage output node based on a fourth control signal; and
a resistance value of the fourth resistor comprised in each of the fourth distribution units is different from the resistance values of the plurality of first resistors comprised in the plurality of first distribution units.

8. The digital-to-analog conversion circuit according to claim 7, wherein the resistance value of the fourth resistor and the resistance values of the plurality of first resistors are not in the geometric sequence.

9. The digital-to-analog conversion circuit according to claim 2, wherein each of the first switch device and the second switch device comprises a transistor.

10. The digital-to-analog conversion circuit according to claim 9, wherein a control terminal of the first switch device is configured to receive the first control signal, an input terminal of the first switch device is electrically connected to a first terminal of the first resistor corresponding to the first switch device, and an output terminal of the first switch device is electrically connected to a second terminal of the first resistor corresponding to the first switch device.

11. The digital-to-analog conversion circuit according to claim 9, wherein a control terminal of the second switch device is configured to receive the second control signal, an input terminal of the second switch device is electrically connected to a first terminal of the second resistor corresponding to the second switch device, and an output terminal of the second switch device is electrically connected to a second terminal of the second resistor corresponding to the second switch device.

12. A display device, comprising a digital-to-analog conversion circuit, wherein the digital-to-analog conversion circuit comprises:
a first resistance distribution module comprises a plurality of first distribution units in series between a first voltage terminal and a voltage output node; each of the first distribution units comprises a corresponding one of a plurality of first resistors, and resistance values of the plurality of first resistors are different from each other and the resistance values of the plurality of first resistors are in a geometric sequence; and
a second resistance distribution module comprises a plurality of second distribution units in series between the voltage output node and a second voltage terminal; each of the second distribution units comprises a corresponding one of a plurality of second resistors, and resistance values of the plurality of second resistors are different from each other and the resistance values of the plurality of second resistors are in the geometric sequence,
wherein each of the first distribution units is configured to enable the first resistor comprised in the first distribution unit to be connected between the first voltage terminal and the voltage output node based on a first control signal, and each of the second distribution units is configured to enable the second resistor comprised in the second distribution unit to be connected between the voltage output node and the second voltage terminal based on a second control signal.

13. The display device according to claim 12, wherein,
each of the first distribution units comprises a first switch device in parallel with the first resistor; and
each of the second distribution units comprises a second switch device in parallel with the second resistor; and
wherein the first switch device of each of the first distribution units is configured to enable the first resistor to be connected between the first voltage terminal and the voltage output node based on the first control signal, and the second switch device of each of the second distribution units is configured to enable the second resistor to be connected between the voltage output node and the second voltage terminal based on the second control signal.

14. The display device according to claim 12, wherein,
a number of the plurality of first distribution units is m1, and the resistance value of the first resistor in an (n1+1)-th one of the plurality of first distribution units is (2\hat{ }n1)R; and
a number of the plurality of second distribution units is m2, and the resistance value of the second resistor in an (n2+1)-th one of the plurality of second distribution units is (2\hat{ }n2)R; and
wherein m1>0, m2>0; m1 and m2 are integers, 0≤n1≤(m1−1), 0≤n2≤(m2−1), and R is an unit cell of the resistance value and is set to have different values according to requirements.

15. The display device according to claim 14, wherein m1 is equal to m2.

16. The display device according to claim 12, wherein the second resistance distribution module further comprises at least one third distribution unit in series with the plurality of second distribution units; each of the at least one third distribution units comprises a third resistor and a third switch device in parallel with the third resistor, and the third switch device of each of the at least one third distribution units is configured to enable the third resistor to be connected between the voltage output node and the second voltage terminal based on a third control signal; and
wherein a resistance value of the third resistor comprised in each of the third distribution units is different from the resistance values of the plurality of second resistors comprised in the plurality of second distribution units.

17. The display device according to claim 16, wherein the resistance value of the third resistor and the resistance values of the plurality of second resistors are not in the geometric sequence.

18. The display device according to claim 12, wherein the first resistance distribution module further comprises at least one fourth distribution unit in series with the plurality of first distribution units; each of the at least one fourth distribution units comprises a fourth resistor and a fourth switch device in parallel with the fourth resistor, and the fourth switch device of each of the at least one fourth distribution units is configured to enable the fourth resistor to be connected between the first voltage terminal and the voltage output node based on a fourth control signal; and
a resistance value of the fourth resistor comprised in each of the fourth distribution units is different from the resistance values of the plurality of first resistors comprised in the plurality of first distribution units.

19. The display device according to claim 18, wherein the resistance value of the fourth resistor and the resistance values of the plurality of first resistors are not in the geometric sequence.

20. The display device according to claim 13, wherein each of the first switch device and the second switch device comprises a transistor.
